(19) United States
(12) Patent Application Publication
(10) Pub. No.: US 2007/0049008 A1
(43) Pub. Date: Mar. 1, 2007

(54) Method for forming a capping layer on a semiconductor device

(76) Inventors: Gerald A. Martin, Round Rock, TX (US); Sam S. Garcia, Austin, TX (US); Varughese Mathew, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/215,375

(22) Filed: Aug. 26, 2005

(51) Int. Cl. H01L 21/4763

(52) U.S. Cl. 438/626; 438/627; 438/675

(57) ABSTRACT

A method for making a semiconductor device includes forming a patterned dielectric overlying active circuitry, the patterned dielectric having a plurality of cavities. A diffusion barrier is formed over the patterned dielectric. A conductive layer is formed over the diffusion barrier in the plurality of cavities. The conductive layer is etched back to be below a top surface of the dielectric, forming recessed areas over the conductive layers in the plurality of cavities. The recessed areas are then filled with a capping film. The capping film and the diffusion barrier are removed to provide a relatively smooth planarized surface. Providing a relatively smooth planarized surface reduces leakage currents between conductors.

### RELATED APPLICATIONS

A related, copending application is entitled “Method Of Forming A Semiconductor Device Having A Diffusion Barrier Stack And Structure Thereof”, by Michaelson et al., application Ser. No. 11/078,236, is assigned to the assignee hereof, and was filed Mar. 11, 2005.

### FIELD OF THE INVENTION

The present invention relates generally to semiconductors, and more particularly, to a method for forming a capping layer on a semiconductor device.

### BACKGROUND OF THE INVENTION

In integrated circuits, a dielectric layer is used to provide insulation around the interconnect wiring of the chip. Just as faster interconnect materials such as copper allow a signal to move faster through the chip, decreasing the capacitance factor of the insulating material also allows signals to travel across the interconnect faster because they have less interference with each other. The most common dielectric material is silicon dioxide. However, the semiconductor industry is constantly searching for commercially useful, lower capacitance dielectric materials, commonly referred to as low dielectric constant or low k materials.

When forming interconnects, the dielectric layer is patterned to form cavities such as trenches, vias, and the like. The cavities are then filled with a conductive material such as copper. To prevent electro-migration or diffusion, a relatively thin barrier layer is formed on the dielectric and the copper is formed on the barrier layer. The barrier layer is typically formed from Ta (tantalum). A chemical mechanical polishing (CMP) process is used to remove the copper and barrier layer from over the dielectric. The copper is recessed in the cavities and a conventional cobalt (Co) film doped with elements like tungsten (W), molybdenum (Mo), rhenium (Re), etc. are formed over the copper to prevent diffusion of copper into the surrounding dielectric material. This can enable integration of copper with low k materials. Also capping copper with these types of materials can enhance reliability by increasing electro-migration resistance. In order to be successful a very selective deposition of these films is required. Also, formation of the capping layer is highly dependent on the condition of the copper surface.

Typically, the cobalt films are deposited on the copper by electroless plating. The plating process may produce a cobalt film having a mushroom shaped profile. The mushroom shape extends above the surface of the dielectric and may cause unacceptable leakage between conductors. In addition, the plating process results in cobalt film with a relatively rough surface.

Therefore, there is a need for a method to form a smooth capping film over copper that minimizes leakage currents between conductors.

### BRIEF DESCRIPTION OF THE DRAWINGS

FIG. 1 illustrates a cross-sectional view of a portion of a semiconductor wafer after formation of an interconnect level.

FIG. 2 illustrates a cross-sectional view of a portion of a semiconductor wafer of FIG. 1 after a portion of a metal layer has been removed.

FIG. 3 illustrates a cross-sectional view of a portion of a semiconductor wafer of FIG. 2 after a further portion of a metal layer has been removed.

FIG. 4 illustrates a cross-sectional view of a portion of the semiconductor wafer of FIG. 3 after formation of a capping layer.

FIG. 5 illustrates a cross-sectional view of a portion of the semiconductor wafer of FIG. 4 after removal of a portion of the capping layer.

### DETAILED DESCRIPTION

Generally, the present invention provides a method for forming a capping layer on top of a conductive metal layer that fills a cavity, such as a via or trench in an interconnect level of a semiconductor device. A purpose of the capping layer is to prevent diffusion of the conductive metal into subsequent interconnect levels within the device.

An active circuitry layer is formed on a substrate. The interconnect level is formed on top of the active circuitry level by depositing a dielectric layer and patterning the dielectric layer to form cavities, which can be vias, trenches, and the like. A diffusion barrier layer, such as tantalum or tantalum nitride, is deposited over the patterned dielectric layer such that the cavities and the top of the patterned dielectric layer are lined with the diffusion barrier layer. A conductive metal, such as copper, is deposited over the diffusion barrier layer, filling the cavities and forming a blanket film over the patterned dielectric layer. The diffusion barrier layer prevents diffusion of the conductive metal into the dielectric layer. The blanket film of the conductive metal is removed by chemical mechanical polishing (CMP) or other planarization method and the conductive metal remains in the cavities. The diffusion barrier layer is not substantially removed with the blanket film of the conductive metal, or in a separate planarization step, and remains on the surface of the patterned dielectric. This remaining diffusion barrier layer protects the dielectric layer from damage from further processing, such as CMP. The conductive metal remaining in the cavities is then recessed through selective chemical etching or deliberate dishing through CMP or other planarization process. The capping layer of cobalt or cobalt doped with other conductive elements is then deposited through electroless plating or other deposition process such that it overfills the recessed area above the conductive metal. The capping layer extending above the cavity and the barrier layer on top of the patterned dielectric layer is removed by a single CMP process or other planarization process. The surface roughness of the capping layer is reduced through this planarization process resulting in reduced leakage.

By leaving the diffusion barrier layer on top of the patterned dielectric layer after the conductive metal layer is removed, the dielectric surface is not exposed during the deposition of the capping layer or during a substantial portion of the simultaneous planarization of the capping layer and removal of the diffusion barrier layer. By not exposing the dielectric layer to the capping layer deposition process, diffusion of materials used in the capping layer deposition process is significantly reduced. In the case of electroless deposition of the capping layer, the remaining diffusion barrier layer substantially prevents the diffusion of metal ions into the dielectric layer resulting in reduced leakage caused by trapping of conductive materials. The remaining diffusion barrier layer also provides additional mechanical strength during the simultaneous planarization of the capping layer and substantial removal of the diffusion barrier layer resulting in reduced damage of the dielectric film. The benefits of reduced mechanical damage and reduced diffusion of contaminants into the dielectric layer are greater when the dielectric layer is a lower dielectric constant material. Furthermore, the method of forming the capping layer is simplified by planarizing the capping layer and removing the diffusion barrier layer remaining on the dielectric layer in one process step rather than in separate steps.

FIG. 1 illustrates a cross-sectional view of a portion of a semiconductor wafer 10. The semiconductor wafer is processed to produce semiconductor devices having integrated circuits implemented thereon. Semiconductor wafer 10 includes a substrate 12 and an active circuitry layer 14 containing a plurality of structures such as transistors, diodes, resistors and other circuit elements. The transistors may be, for example, complementary metal-oxide semiconductor (CMOS) transistors. Substrate 12 can be silicon, silicon-on-insulator, silicon germanium, or other semiconductor material. An interconnect level 16 is formed on a surface of the circuitry layer 14. The interconnect layer 16 consists of a dielectric layer 18 which is patterned to form cavities 15 and remaining vertical structures using conventional photolithography and etch processes. The cavities 15 can be vias, trenches and the like. In one embodiment, the dielectric layer 18 is a carbon-containing silicon oxide but it can be silicon dioxide, doped silicon dioxide, or a porous low dielectric constant material. A diffusion barrier layer 20 is deposited on the dielectric layer 18 and lines the top of the patterned dielectric layer 18 and the sidewalls and bottoms of the cavities 15. The diffusion barrier is deposited by physical vapor deposition (PVD), chemical vapor deposition (CVD) or some other deposition method. In one embodiment, the diffusion barrier layer is tantalum (Ta) but can be tantalum nitride (TaN), titanium nitride (TiN) or other conductive material. A conductive metal layer 22 is deposited on the diffusion barrier layer 20 which fills the cavities 15 and subsequently forms a blanket layer atop the patterned dielectric layer 18 and the diffusion barrier 20. The conductive metal layer 22 can be copper or other conductive metal and is deposited by electroplating, PVD or other deposition technique or combination thereof. In one embodiment, the conductive metal layer 22 can be deposited by forming a seed layer of copper by PVD (not shown) then electroplating copper on top of the seed layer.

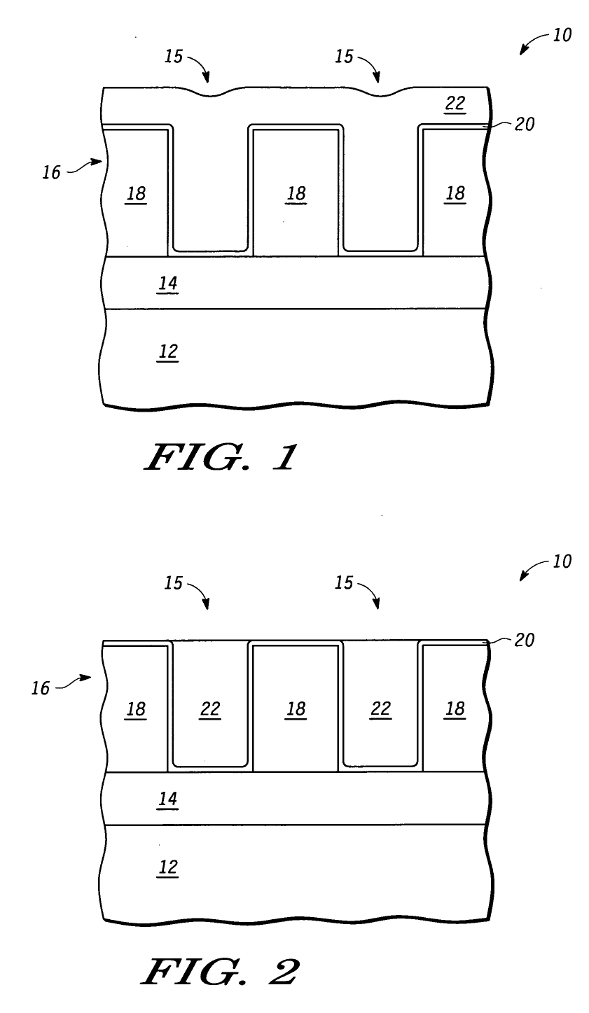

FIG. 2 illustrates a cross-sectional view of the semiconductor device 10 of FIG. 1 after a portion of the conductive metal layer 22 has been removed using a conventional chemical mechanical polishing (CMP) process or another planarization method such as electrochemical mechanical polishing (eCMP). As illustrated in FIG. 2, all of conductive metal layer 22 is removed except for the metal filling the cavities 15. The diffusion barrier layer 20 is not substantially removed in the CMP process. By leaving all or a substantial portion of the diffusion layer 20 atop the patterned dielectric layer 18, the patterned dielectric layer 18 is protected from subsequent processing steps.

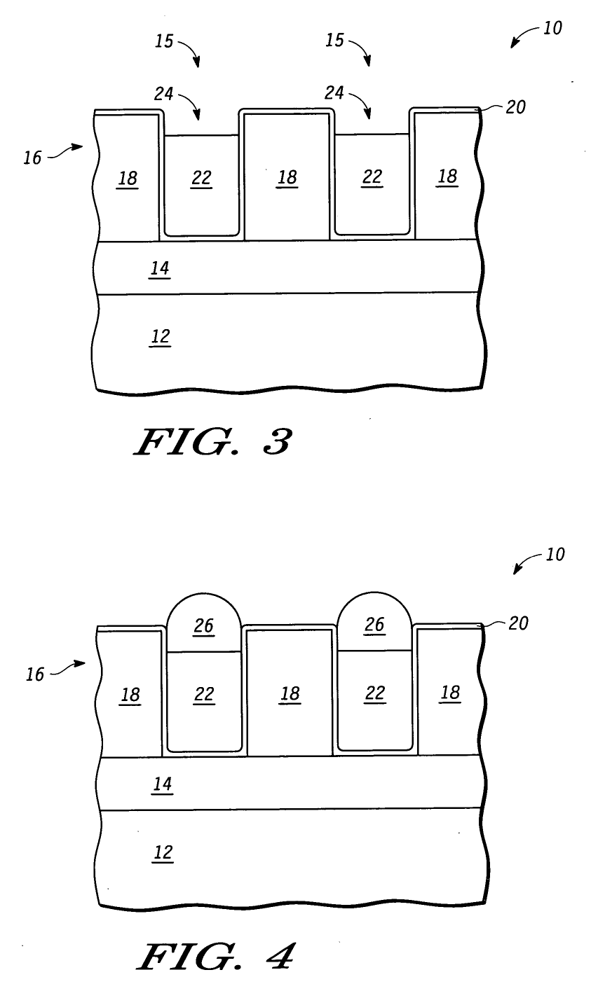

FIG. 3 illustrates a cross-sectional view of the portion of the semiconductor wafer 10 of FIG. 2 after removal of a portion of the conductive metal layer 22 remaining in the cavities 15 to form recessed regions 24 such that the top surface of the remaining conductive metal layer 22 is below the top surface of the patterned dielectric layer 18. The recessed regions 24 in metal layer 22 can be formed by selective chemical etching or deliberate dishing through CMP, eCMP or other planarization process. Note that diffusion layer 20 is not removed at this time. Diffusion layer 20 protects dielectric layer 18 from contaminants and damage that may be caused by subsequent processing steps.

FIG. 4 illustrates a cross-sectional view of the semiconductor wafer 10 of FIG. 3 after selective deposition of capping layer 26. In one embodiment the capping layer 26 is deposited by electroless plating but other selective deposition techniques may be used. The capping layer 26 is a conductive material such as cobalt (Co) and can be doped with other elements such as tungsten (W) or boron (B). In one embodiment the capping layer 26 comprises cobalt (Co), tungsten (W) and boron (B). In the illustrated embodiment, the deposition of the capping layer 26 comprises applying a solution comprising borane, cobalt sulfate, and sodium tungstate or tungstic acid. Also, the capping layer 26 can be doped with elements like nickel (Ni), molybdenum (Mo), rhenium (Re), and phosphorus (P). Ideally, the capping layer 26 would be deposited until completely filling the recessed regions 24 and then stopped. But because deposition of a capping layer comprising cobalt, tungsten and boron may not be easily accurately controllable, more material than needed will be deposited to ensure the recesses are adequately filled. This results in the capping layer 26 having the mushroom shape illustrated in FIG. 4. The capping layer 26 functions to prevent copper from diffusing into any subsequent interconnect level. Also, the capping layer may function to reduce electro-migration.

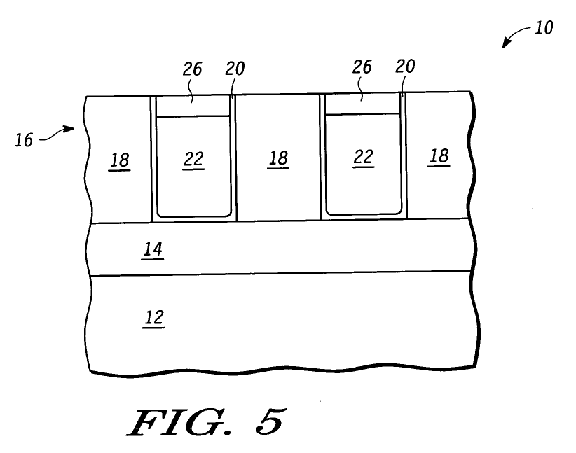

FIG. 5 illustrates a cross-sectional view of the portion of the semiconductor wafer 10 of FIG. 4 after a portion of capping layer 26 and the diffusion barrier layer 20 on the patterned dielectric layer 18 are removed by conventional CMP, eCMP or other planarization method in one step such that the entire top surface of the dielectric layer 18 and the capping layer 26 are planar. Also, the surface roughness of capping layer 26 is reduced by the one planarization step resulting in reduced leakage. In addition, only one platen of a CMP tool is used to remove both the capping layer 26 and the diffusion barrier layer 20 in one CMP process step. This may reduce manufacturing costs by reducing the number of CMP steps required to manufacture the device. Also, by leaving the diffusion barrier layer 20 on after the CMP removal of copper layer 22 illustrated in FIG. 2, the dielectric layer 18 is protected from subsequent processing steps until it is removed as illustrated in FIG. 5. Without the protection provided by diffusion barrier layer 20, the subsequent processing steps may cause contamination or damage to the dielectric layer 18. By leaving the barrier layer on, the dielectric layer 18 is only exposed at the end of the barrier layer/capping layer CMP step of FIG. 5.

While the invention has been described in the context of a preferred embodiment, it will be apparent to those skilled in the art that the present invention may be modified in numerous ways and may assume many embodiments other than that specifically set out and described above. Accordingly, it is intended by the appended claims to cover all modifications of the invention which fall within the true scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a semiconductor device, comprising:
providing a semiconductor substrate having overlying active circuitry;
forming a patterned dielectric over the active circuitry, wherein the patterned dielectric has a cavity;
forming a diffusion barrier over the patterned dielectric wherein the cavity is lined with the diffusion barrier and a top surface of the patterned dielectric is coated with the diffusion barrier;
forming a conductive layer over the diffusion barrier wherein the conductive layer fills the cavity;
etching the conductive layer to remove the conductive layer from over the top surface of the diffusion barrier, without removing a substantial portion of the diffusion barrier;
forming a recessed region in the conductive layer in the cavity, wherein the recessed region is below the top surface of the patterned dielectric layer;
filling the recessed region with a capping layer; and
removing the diffusion barrier from over the top surface of the patterned dielectric and a portion of the capping layer, wherein the diffusion barrier is removed over the top surface of the patterned dielectric and a substantially planar surface is formed between the top surface of the patterned dielectric layer and a top surface of the capping layer.

2. The method of claim 1 wherein the etching the conductive layer, comprises:
performing chemical mechanical polishing (CMP); and
after the performing the CMP, applying a chemical etchant that is selective between the diffusion barrier and the conductive layer.

3. The method of claim 1, wherein removing the diffusion barrier from over the top surface of the patterned dielectric and a portion of the capping layer comprises removing the diffusion barrier and the portion of the capping layer during one chemical mechanical polishing (CMP) process step.

4. The method of claim 1, wherein the patterned dielectric comprises a low k dielectric, the conductor layer comprises copper, the diffusion barrier comprises tantalum, and the capping layer comprises cobalt.

5. The method of claim 4, wherein the capping layer further comprises tungsten and boron.

6. The method of claim 1, wherein the etching the conductive layer comprises performing CMP to remove the conductive layer over the top surface of the patterned dielectric layer and dish out a portion of the conductive layer in the cavity to form the recessed region.

7. The method of claim 1, wherein the filling the recessed region comprises performing selective deposition of cobalt tungsten boron.

8. The method of claim 7, wherein the performing the selective deposition comprises:
applying a solution comprising borane, cobalt sulfate, and sodium tungstate or tungstic acid.

9. The method of claim 1, wherein the forming the conductive layer comprises electroplating copper.

10. The method of claim 1 wherein the etching the conductive layer comprises:
removing by CMP substantially all of the conductive layer over the top surface of the patterned dielectric;
completely removing by CMP the conductive layer from over the top surface of the patterned dielectric and leaving at least a portion of the diffusion barrier over the top surface of the patterned dielectric; and
etching back the conductive layer in the cavity to form the recessed region.

11. The method of claim 1, wherein the removing comprises performing CMP.

12. A method of forming a semiconductor device, comprising:
providing a semiconductor substrate having overlying active circuitry;
forming a patterned dielectric over the active circuitry, wherein the patterned dielectric has a cavity;
forming a diffusion barrier over the patterned dielectric wherein the cavity is lined with the diffusion barrier and a top surface of the patterned dielectric is coated with the diffusion barrier;
by plating, forming a conductive layer over the diffusion barrier wherein the conductive layer fills the cavity;
performing a step for removing the conductive layer over the top surface of the patterned dielectric, leaving at least a portion of the diffusion barrier over the top surface of the patterned dielectric, and removing a portion of the conductive layer in the cavity to form a recessed region below the top surface of the patterned dielectric layer;
filling the recessed region with a capping layer by selective deposition, wherein a top surface of the capping layer is higher than the top surface of the patterned dielectric layer; and
performing a step for removing the diffusion barrier over the top surface of the patterned dielectric, removing a portion of the capping layer, and forming a substantially planar surface between the top surface of the patterned dielectric layer and a top surface of the capping layer.

13. The method of claim 12, wherein the step for removing the diffusion barrier comprises performing CMP.

14. The method of claim 12, wherein the step for removing the conductive layer comprises performing CMP.

15. The method of claim 14 wherein the step for removing the conductive layer further comprises applying an etchant that is selective between the conductive layer and the diffusion barrier to form the recessed region.

16. The method of claim 12, wherein the conductive layer comprises copper and the capping layer comprises cobalt.

17. The method of claim 16, wherein the diffusion barrier comprises tantalum.

18. A method for making a semiconductor device, comprising:
providing a semiconductor substrate having overlying active circuitry;
forming a patterned dielectric over the active circuitry, wherein the patterned dielectric has a cavity;
forming a diffusion barrier over the patterned dielectric wherein the cavity is lined with the diffusion barrier and a top surface of the patterned dielectric is coated with the diffusion barrier;
forming a conductive layer over the diffusion barrier wherein the conductive layer fills the cavity;
planarizing the conductive layer and thereby exposing the diffusion barrier;
forming a recessed region in the cavity below the top surface of the patterned dielectric layer;
filling the recessed region with a capping layer; and
planarizing top surfaces of the patterned dielectric and the capping layer and thereby removing the diffusion barrier over the top surface of the patterned dielectric.

19. The method of claim 18, wherein the conductive layer comprises copper, the diffusion barrier comprises tantalum, and the capping layer comprises cobalt.

20. The method of claim 18, wherein the planarizing the top surfaces and the planarizing the conductive layer are performed by CMP.
